(19) United States
(12) Patent Application Publication
(10) Pub. No.: US 2026/0191072 A1
(43) Pub. Date: Jul. 2, 2026

(54) METHOD FOR MANUFACTURING SEMICONDUCTOR DEVICE

(71) Applicant: Resonac Corporation, Minato-ku, Tokyo (JP)

(72) Inventors: Shuntaro HIRATA, Minato-ku, Tokyo (JP); Tsuyoshi TAZAWA, Minato-ku, Tokyo (JP); Akira YAMAZAKI, Minato-ku, Tokyo (JP); Keiko UENO, Minato-ku, Tokyo (JP); Akiko HAYASHIDE, Minato-ku, Tokyo (JP); Koichi CHABANA, Minato-ku, Tokyo (JP)

(21) Appl. No.: 18/856,053

(22) PCT Filed: Jun. 17, 2024
(86) PCT No.: PCT/JP2024/021925

§ 371 Date: Oct. 11, 2024

(30) Foreign Application Priority Data
Jun. 28, 2023 (JP) 2023-105739

(51) Int. Cl. H10W 72/00; H10W 72/30; H10W 90/00

(52) U.S. Cl. CPC H10W 72/07232; H10W 72/07332; H10W 72/07338; H10W 72/354; H10W 72/856; H10W 90/724; H10W 90/734

(57) ABSTRACT

A method for manufacturing a semiconductor device, which includes heating and pressurizing a laminate including a first circuit member, a second circuit member, and a thermosetting adhesive layer by pressing members to form a temporary pressure-bonded body; and heating the temporary pressure-bonded body in a pressurizing atmosphere to form a connected body. The first circuit member may be a semiconductor chip. The laminate is pressurized by pressing members at a predetermined pressure of 1.50 MPa or less. For a part or the whole of the time for which the laminate is heated and pressurized by pressing members, at least one of the pressing members is heated to a temporary pressure bonding temperature that is equal to or higher than the onset temperature of the thermosetting adhesive layer.

### TECHNICAL FIELD

The present disclosure relates to a method for manufacturing a semiconductor device.

### BACKGROUND ART

In manufacturing of semiconductor devices, a flip chip connection method is sometimes adopted in which a conductive protrusion called a bump is provided as a connection portion on a semiconductor chip or a wiring circuit board and the semiconductor chip is connected to the wiring circuit board or another semiconductor chip via an adhesive by connection of the connection portions to each other. For example, Patent Literature 1 discloses manufacturing a semiconductor device by a flip chip connection method including a step of obtaining a temporary pressure-bonded body in which semiconductor chips are temporarily pressure-bonded to each other; and a step of heating the temporary pressure-bonded body while applying pressure thereto to join the connection portions to each other.

### CITATION LIST

### Patent Literature

Patent Literature 1: International Publication WO 2018/194156

### SUMMARY OF INVENTION

### Technical Problem

In a case where a semiconductor device is manufactured by a method including connecting a connection portion of a semiconductor chip or a semiconductor wafer to a connection portion of another semiconductor chip or the like by metal joining, a part of the connection portion may be crushed along with connection and significantly deformed. A great degree of deformation of the connection portion may cause a decrease in connection reliability.

The present disclosure relates to suppressing deformation of a connection portion along with connection while securing favorable electrical continuity in a case where a semiconductor device is manufactured by a method including connecting a connection portion of a semiconductor chip or a semiconductor wafer to a connection portion of another semiconductor chip or the like by metal joining.

### Solution to Problem

The present disclosure includes the following.
[1] A method for manufacturing a semiconductor device, the method comprising: heating and pressurizing a laminate including a first circuit member having a first connection portion comprising a first metal material, a second circuit member having a second connection portion comprising a second metal material, and a thermosetting adhesive layer that is interposed between the first circuit member and the second circuit member by a pair of facing pressing members, thereby forming a temporary pressure-bonded body in which the first connection portion and the second connection portion are in contact with each other; and heating the temporary pressure-bonded body to a predetermined main pressure bonding temperature in a pressurizing atmosphere, thereby forming a connected body in which the first connection portion and the second connection portion are electrically connected by metal joining between the first metal material and the second metal material, in which the first circuit member is a semiconductor chip or a semiconductor wafer and the second circuit member is a wiring circuit board, a semiconductor chip, or a semiconductor wafer, the laminate is pressurized by the pair of pressing members at a predetermined pressure of 1.50 MPa or less, at least one of the pair of pressing members is heated to a predetermined temporary pressure bonding temperature for a part or whole of time for which the laminate is heated and pressurized by the pair of pressing members, and the temporary pressure bonding temperature is a temperature that is equal to or higher than an onset temperature of the thermosetting adhesive layer and lower than the main pressure bonding temperature, the onset temperature is an onset temperature of an exothermic peak exhibiting a largest calorific value in a DSC curve obtained by differential scanning calorimetry under a condition in which a sample of the thermosetting adhesive layer is heated at a temperature increase rate of 10° C./min, and the main pressure bonding temperature is a temperature equal to or higher than at least one of a melting point of the first metal material or a melting point of the second metal material.
[2] The method according to [1], in which the predetermined pressure is 0.94 MPa or more and 1.50 MPa or less.
[3] The method according to [1] or [2], in which the temporary pressure bonding temperature is equal to or higher than the onset temperature and 200° C. or less.
[4] The method according to any one of [1] to [3], in which the time for which the laminate is heated and pressurized by the pair of pressing members is 5 seconds or less.
[5] The method according to any one of [1] to [4], in which the thermosetting adhesive layer exhibits a shear viscosity of 10000 Pa·s or less at a temperature lower than the onset temperature by 20° C., and the shear viscosity is a value measured under conditions of a temperature increase rate of 10° C./min, a frequency of 10 Hz, and a strain of 1%.
[6] The method according to any one of [1] to [5], in which the time for which the temporary pressure-bonded body is heated to a temperature equal to or higher than at least one of a melting point of the first metal material or a melting point of the second metal material in the pressurizing atmosphere is 60 seconds or less.
[7] The method according to any one of [1] to [6], in which a pressure of the pressurizing atmosphere is higher than atmospheric pressure and 0.90 MPa or less.
[8] The method according to any one of [1] to [7], in which the thermosetting adhesive layer comprises: a thermosetting resin having a molecular weight of less than 10000; a curing agent for the thermosetting resin; and a polymer component having a weight average molecular weight of 10000 or more.
[9] The method according to [8], in which the polymer component has a glass transition temperature of 200° C. or less.
[10] The method according to any one of [1] to [9], in which the thermosetting adhesive layer exhibits a shear viscosity of 10000 Pa·s or more at 40° C.

### Advantageous Effects of Invention

In a case where a semiconductor device is manufactured by a method including connecting a connection portion of a semiconductor chip to a connection portion of another semiconductor chip or the like by metal joining, deformation of the connection portions along with the connection can be suppressed. In addition, favorable electrical continuity between the connection portions is likely to be secured.

### BRIEF DESCRIPTION OF DRAWINGS

FIG. 1 is a process drawing illustrating an example of a method for manufacturing a semiconductor device.

FIG. 2 is a process drawing illustrating an example of a method for manufacturing a semiconductor device.

FIG. 3 is a process drawing illustrating an example of a method for manufacturing a semiconductor device.

FIG. 4 is a schematic drawing illustrating a method for determining an onset temperature from a DSC curve.

FIG. 5 is a cross-sectional photograph of a connection portion in a connected body.

FIG. 6 is a cross-sectional photograph of a connection portion in a connected body.

FIG. 7 is a cross-sectional photograph of a connection portion in a connected body.

FIG. 8 is a cross-sectional photograph of a connection portion in a connected body.

### DESCRIPTION OF EMBODIMENTS

The present invention is not limited to the following examples.

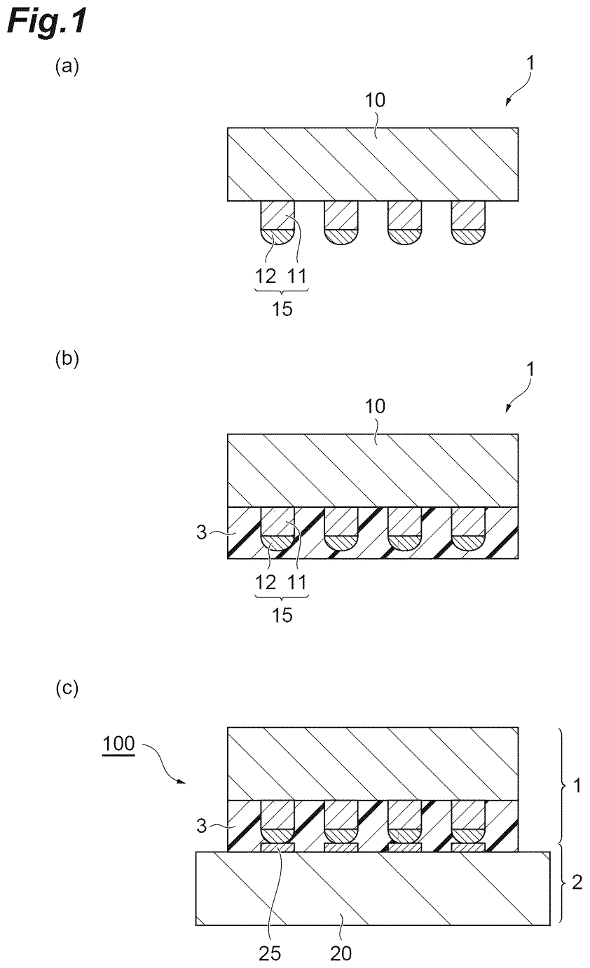

FIGS. 1, 2 and 3 are process drawings illustrating examples of a method for manufacturing a semiconductor device. The method illustrated in FIGS. 1 to 3 includes preparing a laminate 100 including a first circuit member 1 having a first connection portion 15 containing a first metal material, a second circuit member 2 having a second connection portion 25 containing a second metal material, and a thermosetting adhesive layer 3; heating and pressurizing the laminate 100 by a pair of facing pressing members 41 and 42, thereby forming a temporary pressure-bonded body 101 in which the first connection portion 15 and the second connection portion 25 are in contact with each other; and heating the temporary pressure-bonded body 101 to a predetermined main pressure bonding temperature in a pressurizing atmosphere, thereby forming a connected body 102 (a semiconductor device) in which the first connection portion 15 and the second connection portion 25 are electrically connected by metal joining between the first metal material and the second metal material. The first circuit member 1 may be a semiconductor chip or a semiconductor wafer. The second circuit member 2 may be a printed circuit board, a semiconductor chip, or a semiconductor wafer.

As illustrated in FIG. 1, the laminate 100 is prepared, for example, by a method including preparing the first circuit member 1 (for example, a semiconductor chip) having a plate-shaped main body 10 and a plurality of first connection portions 15 disposed on a main surface of the main body 10; providing the thermosetting adhesive layer 3 on a surface on a first connection portion 15 side of the first circuit member 1; preparing the second circuit member 2 having a plate-shaped main body 20 and the second connection portion 25 disposed on a main surface of the main body 20; and disposing the first circuit member 1 on the second circuit member 2 so that the thermosetting adhesive layer 3 is interposed between the first circuit member 1 and the second circuit member 2 and the first connection portion 15 and the second connection portion 25 are disposed to face each other.

The main body 10 of the first circuit member 1 (semiconductor chip or semiconductor wafer) is not particularly limited and can be those having various types of semiconductor substrates and integrated circuits. The main body 10 may include, for example, elemental semiconductors composed of the same kinds of elements such as silicon and germanium, or may include compound semiconductors such as gallium arsenide and indium phosphide.

The first connection portion 15 of the first circuit member 1 has a metal pillar 11 and a bump 12 provided on the metal pillar 11. The first metal material is contained in the bump 12 that is the portion joined to the second connection portion 25. The metal pillar 11 may be, for example, a copper pillar. The melting point of the first metal material contained in the bump 12 may be 220° C. or more and 330° C. or less or 140° C. or more and 220° C. or less. The bump 12 may be a solder bump containing solder as the first metallic material. The first metal material may be a solder containing a Sn—Ag alloy, a Sn—Pb alloy, a Sn—Bi alloy, a Sn—Cu alloy, or a Sn—Ag—Cu alloy.

The wiring circuit board as the second circuit member 2 has, for example, an insulating substrate as the main body 20 and wiring that is provided on the insulating substrate and includes the second connection portion 25. The insulating substrate may be, for example, a glass epoxy substrate, a polyimide resin substrate, a polyester resin substrate, or a ceramic substrate. The semiconductor chip as the second circuit member 2 can be those having a semiconductor substrate and an integrated circuit, similarly to the first circuit member 1. The semiconductor wafer as the second circuit member 2 can include a plurality of portions corresponding to semiconductor chips.

The second connection portion 25 of the second circuit member 2 can be, for example, a metal pad containing a second metal material. The second metal material may be, for example, gold, silver, copper, solder, tin, nickel, or any combination thereof. Solder as the second metal material may contain a Sn—Ag alloy, a Sn—Pb alloy, a Sn—Bi alloy, a Sn—Cu alloy, or a Sn—Ag—Cu alloy.

The thermosetting adhesive layer 3 is a layer formed of a thermosetting adhesive, and is provided on the first circuit member 1 by, for example, attaching a film-shaped thermosetting adhesive formed in advance to the first circuit member 1. The film-shaped thermosetting adhesive can be attached to the first circuit member 1 by, for example, hot pressing, roll lamination, or vacuum lamination. The area and thickness of the film-shaped thermosetting adhesive are appropriately set depending on the size of the first circuit member 1, the height of the first connection portion 15, and the like. The thickness of the film-shaped thermosetting adhesive and the thermosetting adhesive layer 3 may be, for example, 1 μm or more and 60 μm or less. By dicing the semiconductor wafer to which the film-shaped thermosetting adhesive is attached into individual pieces, a semiconductor chip to which a thermosetting adhesive layer 3 is attached may be prepared as the first circuit member 1. The thermosetting adhesive layer 3 and the thermosetting adhesive that forms this will be described in detail later.

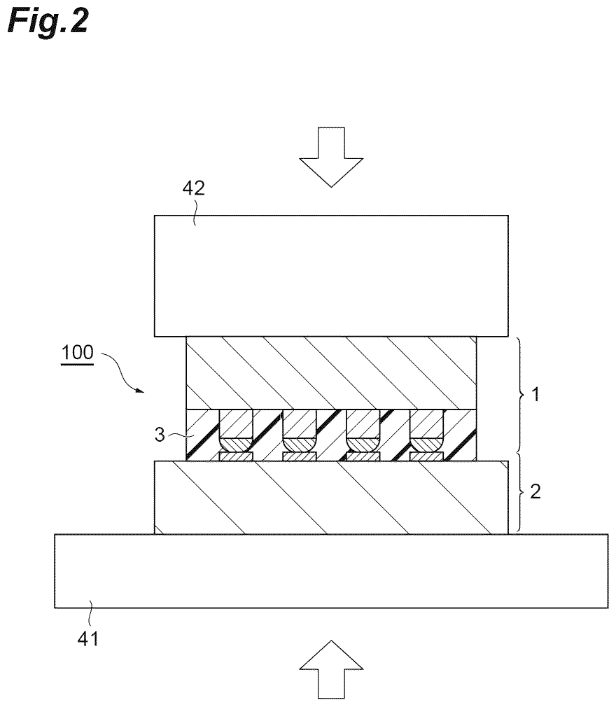

As illustrated in FIG. 2, the pair of pressing members 41 and 42 are disposed to face each other, and the laminate 100 is heated and pressurized by being sandwiched between the pressing member 41 disposed on the second circuit member 2 side and the pressing member 42 disposed on the first circuit member 1 side. The temporary pressure-bonded body 101 is formed by the temporary pressure bonding step including this heating and pressurization. For a part or the whole time for which the laminate 100 is heated and pressurized by the pressing members 41 and 42, the pressing member 41, the pressing member 42, or both of these are heated to a predetermined temporary pressure bonding temperature.

The laminate 100 is heated by heat transfer from the pressing member in contact with the laminate 100. For example, the pressing member 41 disposed on the second circuit member 2 side may be a stage, and the pressing member 42 on the first circuit member 1 side may be a crimping head. The first circuit member 1 may be adsorbed to the pressing member 42 that is a crimping head, and the connection portions may be aligned by movement of the crimping head. For this, a crimping machine such as a flip chip bonder having a crimping head can be used. The first circuit member 1 adsorbed to the pressing member 42 that is a crimping head and the thermosetting adhesive layer 3 may be disposed on the second circuit member 2 to form the laminate 100, and the laminate 100 may be pressurized by the crimping head (pressing member 42) as it is.

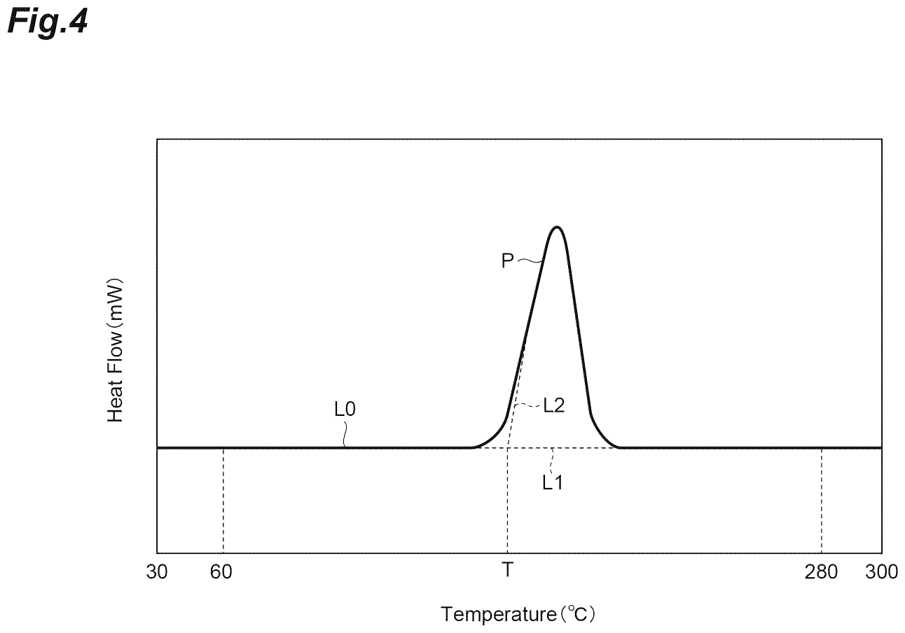

The temporary pressure bonding temperature is a constant temperature set in a range equal to or higher than the onset temperature of the thermosetting adhesive layer 3. The onset temperature here is the onset temperature of the exothermic peak exhibiting the largest calorific value in a DSC curve obtained by differential scanning calorimetry under a condition in which a sample that is a part of the thermosetting adhesive layer 3 is heated at a temperature increase rate of 10° C./min. FIG. 4 is a schematic drawing illustrating a method for determining the onset temperature from a DSC curve. The DSC curve illustrated in FIG. 4 includes a baseline L0 and an exothermic peak P due to the curing reaction of the thermosetting adhesive layer 3, which is observed midway along the baseline L0 in the temperature region of 60° C. to 280° C. The temperature T at the intersection point of an extension line L1 of the baseline L0 below the exothermic peak P and a tangent L2 to the DSC curve at a point where the DSC curve shows the maximum gradient on the lower temperature side of the temperature at which the exothermic peak P shows the largest maximum value is the onset temperature. The exothermic peak may include one or more shoulder peaks in addition to a maximum peak showing the largest maximum value. In a case where the exothermic peak includes one or more shoulder peaks located on the lower temperature side of the temperature at which the largest maximum value is shown, the temperature at the intersection point of a tangent to the DSC curve at the point where the DSC curve on the lower temperature side of the shoulder peak located on the lowest temperature side shows the maximum gradient and an extension line of the baseline of the DSC curve is taken as the onset temperature.

When the temporary pressure bonding temperature is equal to or higher than the onset temperature, the viscosity of the thermosetting adhesive layer 3 significantly decreases during the heating and pressurization for forming the temporary pressure-bonded body, and thus the thermosetting adhesive layer 3 is likely to be sufficiently eliminated from between the first connection portion 15 and the second connection portion 25. Therefore, favorable electrical continuity is likely to be secured when the conditions of heating and pressurization in the main pressure bonding step for forming the connected body 102 from the temporary pressure-bonded body 101 are relatively mild as well. As a result, deformation of the connection portion (for example, bump 12) of the connected body 102 may be suppressed.

From this point of view, the temporary pressure bonding temperature may be a temperature higher than the onset temperature by 1° C., 2° C., 3° C., 4° C., or 5° C. or more. The temporary pressure bonding temperature may be 200° C. or less, 195° C. or less, 190° C. or less, or 185° C. or less. The temporary pressure bonding temperature is usually a temperature lower than the melting point of the first metal material and the melting point of the second metal material.

The onset temperature of the thermosetting adhesive layer 3 may be, for example, 140° C. or more and 190° C. or less. The onset temperature of the thermosetting adhesive layer 3 may be 145° C. or more, 150° C. or more, or 155° C. or more and may be 185° C. or less, 180° C. or less, 175° C. or less, 170° C. or less, or 165° C. or less.

While the laminate 100 is heated and pressurized by the pressing members 41 and 42, the temperature (heating temperature) of the pressing member 41, the pressing member 42, or both of these may be substantially maintained at a constant temporary pressure bonding temperature equal to or higher than the onset temperature, or may fluctuate. However, in a case where the heating temperature is substantially maintained at a constant temporary pressure bonding temperature as well, the actual heating temperature may fluctuate to a certain extent (for example, in a range of the temporary pressure bonding temperature ±1° C.). In a case where the heating temperature fluctuates, the maximum temperature is set to be the predetermined temporary pressure bonding temperature.

When the time (temporary pressure bonding time) for which the laminate 100 is heated and pressurized by the pressing members 41 and 42 is appropriately short, there is a tendency that the curing reaction of the thermosetting adhesive layer 3 is less likely to proceed excessively at the stage prior to heating at the main pressure bonding temperature. Therefore, the temporary pressure bonding time may be 5 seconds or less, 4 seconds or less, 3 seconds or less, or 2 seconds or less, or may be 0.5 seconds or more, or 1 second or more.

In order to form the temporary pressure-bonded body 101, a predetermined pressure is applied to the laminate 100 by the pressing members 41 and 42. When this pressure is properly low, it is easy to suppress deformation of the connection portions while sufficiently eliminating voids and the thermosetting adhesive layer 3 from between the connection portions. From this point of view, the predetermined pressure for forming the temporary pressure-bonded body 101 may be 1.50 MPa or less, or may be 0.94 MPa or more and 1.50 MPa or less. Pressurization at a pressure in this range may be advantageous from the viewpoint of avoiding a decrease in connection reliability due to breakage of the connection portion as well. From the same viewpoint, the predetermined pressure for forming the temporary pressure-bonded body 101 may be 1.45 MPa or less, 1.40 MPa or less, or 1.35 MPa or less, or may be 1.0 MPa or more, 1.05 MPa or more, or 1.1 Ma or more. In order to form the temporary pressure-bonded body 101, the load applied to the entire laminate 100 by the pressing members 41 and 42 may be 50 N or more and 80 N or less.

An additional thermosetting adhesive layer and an additional circuit member (for example, a semiconductor chip) may further be provided on the side of the first circuit member 1 opposite to the second circuit member 2. In this case, the respective circuit members may be laminated in sequence by a temporary pressure bonding step, or a temporary pressure-bonded body may be formed by a temporary pressure bonding step of collectively heating and pressurizing a laminate having three or more circuit members. In a case where three or more circuit members are laminated, a semiconductor chip having a TSV structure may be used as a circuit member.

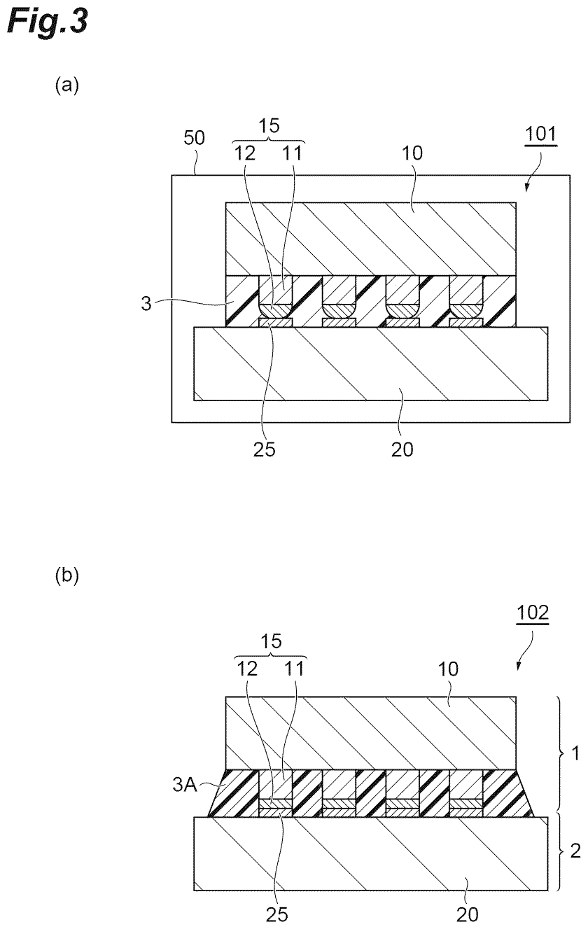

Subsequently, as illustrated in (a) of FIG. 3, the connected body 102 is formed by a main pressure bonding step of heating the temporary pressure-bonded body 101 to a predetermined main pressure bonding temperature in a pressurizing atmosphere in a heating furnace 50. The main pressure bonding temperature for forming the connected body 102 is set to a range equal to or higher than at least one of the melting point of the first metal material or the melting point of the second metal material. As the temporary pressure-bonded body 101 is heated to a heating temperature that reaches the main pressure bonding temperature that is equal to or higher than at least one of the melting point of the first metal material or the melting point of the second metal material, metal joining between the first metal material and the second metal material is formed. For example, in the main pressure bonding step, as the bump 12 of the first connection portion 15 melts and the deformed bump 12 is interposed between the metal pillar 11 and the second connection portion 25, the first connection portion 15 and the second connection portion 25 are electrically connected to each other.

The curing reaction of the thermosetting adhesive layer 3 also proceeds by heating in the main pressure bonding step, and an adhesive layer 3A that is a cured thermosetting adhesive is formed. For example, the connected body 102 can be a semiconductor device including a semiconductor chip as the first circuit member 1, the second circuit member 2, and the adhesive layer 3A. After the main pressure bonding step, the connected body 102 may be further heated to further advance the curing reaction of the thermosetting adhesive.

The heating furnace 50 may be, for example, a pressure reflow furnace or a pressure oven. The gas forming the pressurizing atmosphere in the heating furnace 50 may include air, nitrogen, or formic acid.

The heating temperature of the temporary pressure-bonded body 101 in the main pressure bonding step may be constant or may fluctuate, but the temporary pressure-bonded body 101 is heated so that the maximum temperature becomes the main pressure bonding temperature. The heating temperature here can be the temperature of the pressurizing atmosphere.

The main pressure bonding temperature may be, for example, 220° C. or more and 330° C. or less. When the main pressure bonding temperature is in this range, it is easy to favorably form metal joining while suppressing scattering of the connection portion and formation of voids in the connection portion due to excessive alloy growth accompanying metal joining. This tendency is remarkable, for example, in a case where the first metal material or the second metal material is solder.

In the main pressure bonding step, the time for which the temporary pressure-bonded body 101 is heated to a temperature equal to or higher than at least one of the melting point of the first metal material or the melting point of the second metal material may be 60 seconds or less. Alternatively, in the main pressure bonding step, the time for which the temporary pressure-bonded body 101 is heated to 220° C. or more may be 60 seconds or less. According to the main pressure bonding step under this condition, it is easy to favorably form metal joining while suppressing scattering of the connection portion and formation of voids in the connection portion due to excessive alloy growth accompanying the metal joining. In the main pressure bonding step, the time for which the temporary pressure-bonded body 101 is heated to a temperature equal to or higher than at least one of the melting point of the first metal material or the melting point of the second metal material may be 5 seconds or more. In the main pressure bonding step, the time for which the temporary pressure-bonded body 101 is heated to 220° C. or more may be 5 seconds or more.

Before being heated to the main pressure bonding temperature, the temporary pressure-bonded body 101 may be heated in a pressurizing atmosphere at a certain preheating temperature that is lower than the melting point of the first metal material and the melting point of the second metal material. Heating at this preliminary temperature may contribute to suppression of voids in the connection portion. The time for which the temporary pressure-bonded body 101 is heated at a certain preheating temperature may be 1 minute or more or 2 minutes or more, or may be 20 minutes or less or 15 minutes or less. The preheating temperature may be higher than the temporary pressure bonding temperature, or may be 160° C. or more, 165° C. or more, or 170° C. or more. The preheating temperature may be 200° C. or less, 195° C. or less, 190° C. or less, 185° C. or less, or 180° C. or less.

The pressure of the pressurizing atmosphere in the heating furnace 50 is appropriately set depending on the size and number of circuit members, and the like. The pressure of the pressurizing atmosphere may be, for example, higher than atmospheric pressure and 1 MPa or less. A higher pressure may contribute to, for example, suppression of voids and improvement in connectivity. A lower pressure may contribute to suppression of fillets. From these points of view, the pressure of the pressurizing atmosphere may be, for example, higher than atmospheric pressure and 0.90 MPa or less or may be 0.20 MPa or more and 0.80 MPa or less.

A plurality of temporary pressure-bonded bodies may be collectively heated in one heating furnace 50. The pressurizing atmosphere makes it possible to pressurize the plurality of temporary pressure-bonded bodies in high uniformity. When the temporary pressure-bonded body is heated in the pressurizing atmosphere, the generation of fillets, which are adhesive layer protruding from the outer circumference portion of the connected body, also tends to be suppressed compared to a case where the temporary pressure-bonded body is heated and pressurized using pressing members.

Hereinafter, the thermosetting adhesive layer 3 and the thermosetting adhesive that forms this will be described in detail.

The thermosetting adhesive layer 3 may be a layer formed from a thermosetting adhesive containing a thermosetting resin having a molecular weight of less than 10000, a curing agent for the thermosetting resin, and a polymer component having a weight average molecular weight of 10000 or more.

The thermosetting resin is a compound that forms a cross-linked polymer by a curing reaction, and examples thereof include an epoxy resin. The epoxy resin can be a compound having two or more epoxy groups. Examples of the epoxy resin include a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin and a dicyclopentadiene type epoxy resin. These can be used singly or in combination of two or more kinds thereof. The weight average molecular weight of the epoxy resin is usually less than 10000. In this specification, the weight average molecular weight means a value calculated in terms of standard polystyrene as measured by gel permeation chromatography (GPC).

The content of the epoxy resin may be 5% by mass or more and 75% by mass or less, 10% by mass or more and 50% by mass or less, or 15% by mass or more and 35% by mass or less based on the mass of the thermosetting adhesive layer 3 or the total mass of the components of the thermosetting adhesive other than the solvent.

The curing agent is a component that advances the curing reaction of the thermosetting resin. Examples of the curing agent in a case where the thermosetting resin is an epoxy resin include a phenolic resin-based curing agent, an acid anhydride-based curing agent, an amine-based curing agent, an imidazole-based curing agent, and a phosphine-based curing agent. The curing agent may include one or more selected from a phenolic resin-based curing agent, an acid anhydride-based curing agent, an amine-based curing agent, or an imidazole-based curing agent, or may include an imidazole-based curing agent.

The phenolic resin-based curing agent is a compound having two or more phenolic hydroxyl groups, and examples thereof include phenol novolac, cresol novolac, a phenol aralkyl resin, a cresol naphthol formaldehyde polycondensate, a triphenylmethane type polyfunctional phenol, and other polyfunctional phenolic resins. These can be used singly or in combination of two or more kinds thereof.

The equivalent ratio of the phenolic resin-based curing agent to the epoxy resin (phenolic hydroxyl group/epoxy group, molar ratio) may be 0.3 to 1.5, 0.4 to 1.0, or 0.5 to 1.0 from the viewpoints of favorable curing properties, adhesive properties and storage stability.

Examples of the acid anhydride-based curing agent include methylcyclohexanetetracarboxylic dianhydride, trimellitic anhydride, pyromellitic anhydride, benzophenone tetracarboxylic dianhydride and ethylene glycol bis(anhydrotrimellitate). These can be used singly or in combination of two or more kinds thereof.

The equivalent ratio of the acid anhydride-based curing agent to the epoxy resin (acid anhydride group/epoxy group, molar ratio) may be 0.3 to 1.5, 0.4 to 1.0, or 0.5 to 1.0 from the viewpoints of favorable curing properties, adhesive properties and storage stability.

The amine-based curing agent is a compound having an amino group, and examples thereof include dicyandiamide.

The equivalent ratio of the amine-based curing agent to the epoxy resin (amine/epoxy group, molar ratio) may be 0.3 to 1.5, 0.4 to 1.0, or 0.5 to 1.0 from the viewpoints of favorable curing properties, adhesive properties and storage stability.

The imidazole-based curing agent is an imidazole derivative, and examples thereof include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-2,4-diamino-6-[2′-ethyl-4′-undecylimidazolyl-(1′)]-ethyl-s-triazine, methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5-hydroxymethylimidazole and adducts of epoxy resins and imidazoles. From the viewpoints of excellent curing properties, storage stability and connection reliability, the imidazole-based curing agent may be selected from 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, or 2-phenyl-4-methyl-5-hydroxymethylimidazole. These can be used singly or in combination of two or more kinds thereof. Microcapsules containing these can also be used as a latent curing agent.

The content of the imidazole-based curing agent may be 0.1 to 20 parts by mass, 0.1 to 10 parts by mass, or 3.2 to 5.5 parts by mass with respect to 100 parts by mass of the epoxy resin.

Examples of the phosphine-based curing agent include triphenylphosphine, tetraphenylphosphonium tetraphenylborate, tetraphenylphosphonium tetra(4-methylphenyl) borate and tetraphenylphosphonium (4-fluorophenyl) borate.

The content of the phosphine-based curing agent may be 0.1 to 10 parts by mass or 0.1 to 5 parts by mass with respect to 100 parts by mass of the epoxy resin.

The polymer component may contribute to the heat resistance and film forming properties of the thermosetting adhesive layer. Examples of the polymer component include a phenoxy resin, a polyimide resin, a polyamide resin, a polycarbodiimide resin, a cyanate ester resin, an acrylic resin, a polyester resin, a polyethylene resin, a polyethersulfone resin, a polyetherimide resin, a polyvinyl acetal resin, a urethane resin and acrylic rubber. The polymer component may be a copolymer containing a partial structure corresponding to the resin or rubber selected from these. From the viewpoints of heat resistance and film forming properties, the polymer component may include one or more selected from a phenoxy resin, a polyimide resin, acrylic rubber, a cyanate ester resin, or a polycarbodiimide resin. The polymer component may include one or more selected from a phenoxy resin, a polyimide resin, or acrylic rubber. These polymer components can be used singly or in combination of two or more kinds thereof. In this specification, the polymer component is a component different from the thermosetting resin (for example, epoxy resin) described above.

The glass transition temperature (Tg) of the polymer component may be 200° C. or less, 50° C. or more and 200° C. or less, 50° C. or more and 180° C. or less, or 50° C. or more and 150° C. or less from the viewpoint of the attaching properties of the film-shaped thermosetting adhesive to the circuit member. When the Tg of the polymer component is 50° C. or more, the tacky (viscous) force of the thermosetting adhesive tends to be properly weak. When the Tg of the polymer component is 200° C. or less, the thermosetting adhesive is likely to properly fill in irregularities caused by the connection portions of the circuit members, and the like, and as a result, the effect of suppressing voids tends to be relatively great. The Tg here means a value measured using a DSC (DSC-Pyirs1, manufactured by PerkinElmer Inc.) under conditions of a sample amount of 10 mg, a temperature increase rate of 10° C./min, and an air atmosphere.

The weight average molecular weight of the polymer component may be 30000 or more, 40000 or more, or 50000 or more, or may be 200000 or less.

The ratio Ca/Cd (mass ratio) of the epoxy resin content Ca to the polymer component content Cd may be 0.01 to 5, 0.05 to 3, or 0.1 to 2. When the ratio Ca/Cd is 0.01 or more, more favorable curing properties and adhesive strength are likely to be obtained. When the ratio Ca/Cd is 5 or less, more favorable film forming properties are likely to be obtained.

The thermosetting adhesive layer 3 and the thermosetting adhesive may contain a fluxing agent. The fluxing agent can be, for example, a compound having a group represented by Formula (1). The fluxing agent can be one kind of compound represented by Formula (1) alone or a combination of two or more kinds thereof.

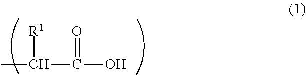

In Formula (1), R¹ represents an electron donating group. Examples of the electron donating group include an alkyl group, a hydroxyl group, an amino group, an alkoxy group, and an alkylamino group. The electron donating group may be an alkyl group, a hydroxyl group or an alkoxyl group, or may be an alkyl group.

R¹ may be an alkyl group having 1 to 10 carbon atoms or 1 to 5 carbon atoms. The alkyl group may be linear or branched, or may be linear. In a case where the alkyl group is linear, the number of carbon atoms in the alkyl group may be equal to or less than the number of carbon atoms in the main chain containing a carboxylic acid from the viewpoint of steric hindrance.

R¹ may be an alkoxy group having 1 to 10 carbon atoms or 1 to 5 carbon atoms. The alkyl group moiety of the alkoxy group may be linear or branched, or may be linear. In a case where the alkyl group moiety of the alkoxy group is linear, the number of carbon atoms therein may be equal to or less than the number of carbon atoms in the main chain containing a carboxylic acid from the viewpoint of steric hindrance.

The alkylamino group as R¹ may be, for example, a monoalkylamino group or a dialkylamino group. The monoalkylamino group may have 1 to 10 carbon atoms or 1 to 5 carbon atoms. The alkyl group moiety of the monoalkylamino group may be linear or branched, or may be linear. The dialkylamino group may have 1 to 20 carbon atoms or 1 to 10 carbon atoms. The alkyl group moiety of the dialkylamino group may be linear or branched, or may be linear.

The fluxing agent may be a compound (dicarboxylic acid) having two carboxyl groups. The compound having two carboxyl groups is less likely to volatilize even at high temperatures during connection compared to a compound (monocarboxylic acid) having one carboxyl group, and the generation of voids can be further suppressed. The compound having two carboxyl groups can further suppress an increase in viscosity of the adhesive during storage, connection work, and the like compared to a case where a compound having three or more carboxyl groups is used. As a result, the connection reliability of the semiconductor device can be further improved.

The fluxing agent may contain a compound represented by the following Formula (2). In Formula (2), R¹ represents an electron donating group, R² represents a hydrogen atom or an electron donating group, and n represents an integer 0 to 10. n may be an integer 2 to 10 or an integer 2 to 8. The fluxing agent containing the compound represented by Formula (2) may contribute to the improvement in reflow resistance and connection reliability of the semiconductor device.

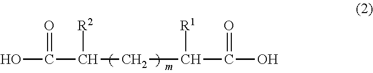

The fluxing agent may contain a compound in which an electron donating group is substituted at position 2 in a dicarboxylic acid selected from succinic acid, glutaric acid, adipic acid, pimelic acid, suberic acid, azelaic acid, sebacic acid, undecanedioic acid, or dodecanedioic acid.

The melting point of the fluxing agent may be 150° C. or less, 140° C. or less, or 130° C. or less. The melting point of the fluxing agent may be 25° C. or more or 50° C. or more. The melting point of the fluxing agent can be measured by using, for example, an instrument in which a capillary tube packed with a sample is attached to a double-tube thermometer and heating is performed in a warm bath as an instrument. The melting point of the fluxing agent may be higher than the temporary pressure bonding temperature for forming the temporary pressure-bonded body.

The content of the fluxing agent may be 0.5% to 10% by mass or 0.5% to 5% by mass based on the mass of the thermosetting adhesive layer 3 or the total mass of the components of the thermosetting adhesive other than the solvent.

The thermosetting adhesive layer 3 and the thermosetting adhesive may further contain a filler. The filler can be an inorganic filler, an organic filler, or a combination thereof.

Examples of the inorganic filler include glass, silica, alumina, titanium oxide, carbon black, mica, and boron nitride. The inorganic filler may be one or more selected from silica, alumina, titanium oxide, and boron nitride, or silica, alumina, or boron nitride. The filler may be a whisker, and examples thereof include aluminum borate, aluminum titanate, zinc oxide, calcium silicate, magnesium sulfate, and boron nitride.

The organic filler may be a resin filler, and examples thereof include particles containing a resin selected from polyurethane, polyimide, a methyl methacrylate resin, and a methyl methacrylate-butadiene-styrene copolymer resin (MBS).

The content of the filler may be 30% to 90% by mass, 30% to 80% by mass, or 30% to 50% by mass based on the mass of the thermosetting adhesive layer 3 or the total mass of the components of the thermosetting adhesive other than the solvent.

The thermosetting adhesive layer 3 and the thermosetting adhesive may further contain other components such as an ion trapper, an antioxidant, a silane coupling agent, a titanium coupling agent, and a leveling agent. These may be used singly or in combination of two or more kinds thereof.

The thermosetting adhesive for forming the thermosetting adhesive layer 3 may further contain a solvent that dissolves or disperses each component. By a method that includes applying a thermosetting adhesive (resin varnish) containing a solvent to a base film and then drying the coating film, a film-shaped thermosetting adhesive can be produced.

The solvent used in the preparation of resin varnish is selected from those that can uniformly dissolve or disperse each component. The solvent can be an organic solvent, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof.

Examples of the base film include polyolefin films such as a polypropylene film and a polymethylpentene film; polyester films such as a polyethylene terephthalate film and a polyethylene naphthalate film;

polyimide films; and polyetherimide films. The base film may be monolayer films formed of these films, or may be a multi-layer film composed of two or more types of films.

When the thermosetting adhesive layer 3 has high fluidity near the onset temperature, favorable electrical continuity is likely to be secured. Therefore, the thermosetting adhesive layer 3 may exhibit a shear viscosity of 10000 Pa·s or less, 9000 Pa·s or less, 8000 Pa·s or less, 7000 Pa·s or less, 6000 Pa·s or less, 5000 Pa·s or less, 4000 Pa·s or less, 3000 Pa·s or less, or 2000 Pa·s or less at a temperature lower than its onset temperature by 20° C. The thermosetting adhesive layer 3 may exhibit a shear viscosity of 500 Pa·s or more or 1000 Pa·s or more at a temperature lower than its onset temperature by 20° C.

The shear viscosity of the thermosetting adhesive layer 3 at 40° C. may be 10000 Pa·s or more or may be 200000 Pa·s or less or 150000 Pa·s or less.

The minimum value of shear viscosity (minimum melt viscosity) of the thermosetting adhesive layer 3 may be 500 Pa·s or more and 3000 Pa·s or less or 800 Pa·s or more and 2500 Pa·s or less. When the minimum melt viscosity of the thermosetting adhesive layer 3 is in this range, there is a tendency that voids are less likely to remain in the adhesive layer. Moreover, in the temporary pressure bonding step, there is a tendency that the thermosetting adhesive is likely to be sufficiently eliminated from between the connection portions.

The shear viscosity of the thermosetting adhesive layer 3 at each temperature and the minimum value of the shear viscosity can be values read from a viscosity curve that shows the relation between shear viscosity (complex viscosity) and temperature, and is obtained when the viscoelasticity of a sample of the thermosetting adhesive layer 3 is measured under the conditions of a temperature increase rate of 10° C./min, a frequency of 10 Hz, and a strain of 1%. The sample for viscoelasticity measurement may be, for example, a laminate with a thickness of 300 to 450 μm obtained by laminating a plurality of thermosetting adhesive layers. The viscosity measuring instrument may be, for example, ARES manufactured by TA Instruments, Inc.

The shear viscosity of the thermosetting adhesive layer 3 can be adjusted to be in a desired range, for example, by adjusting the kind and content of the polymer component or filler.

The gelling time of the thermosetting adhesive layer 3 at 200° C. may be 10 seconds or more and 30 seconds or less. A gelling time in this range may contribute to suppression of void remaining and improvement in connection reliability. The gelling time is the time from when the thermosetting adhesive layer 3 is placed on a hot plate at 200° C. until the thermosetting adhesive layer 3 gels. The gelling time of the thermosetting adhesive layer 3 can be adjusted by the kind and content of the curing agent.

### EXAMPLES

The present invention is not limited to the following Examples.
1. Raw materials
   (a) Epoxy resin
      Polyfunctional solid epoxy resin having triphenolmethane skeleton (EP1032H60, manufactured by Mitsubishi Chemical Corporation, weight average molecular weight: 800 to 2000)
      Bisphenol F type liquid epoxy resin (YL983U, manufactured by Mitsubishi Chemical Corporation, molecular weight:about 336)
      Flexible semi-solid epoxy resin (YX7110B80, manufactured by Mitsubishi Chemical Corporation, weight average molecular weight: 1000 to 5000)
   (b) Curing agent
      2,4-diamino-6-[2′-methylimidazolyl-(1′)]-ethyl-s-triazine isocyanuric acid adduct (2MAOK-PW, manufactured by SHIKOKU CHEMICALS CORPORATION)
   (c) Polymer component
      Phenoxy resin (FX-293, manufactured by NIPPON STEEL Chemical & Material Co., Ltd., Tg:about 160° C., weight average molecular weight: 40000 to 50000)
   (d) Fluxing agent
      Glutaric acid (manufactured by Tokyo Chemical Industry Co., Ltd., melting point: about 98° C.)
   (e) Filler
   Inorganic filler.
      Silica filler (SE2030, manufactured by ADMATECHS COMPANY LIMITED, average particle size: 500 nm)
      Epoxysilane surface-treated silica filler (SE2030, manufactured by ADMATECHS COMPANY LIMITED, average particle size: about 500 nm)
      Methacrylic surface-treated nano silica filler (YA050C, manufactured by ADMATECHS COMPANY LIMITED, average particle size: about 50 nm)
   Organic filler
      Resin filler (EXL-2655, manufactured by The Dow Chemical Company, core-shell type organic fine particles)

### 2. Preparation of Film-Type Thermosetting Adhesive

A resin varnish containing the respective raw materials at the ratio (parts by mass) shown in Table 1 was applied to a base film, and the coating film was dried to prepare two kinds of film-shaped thermosetting adhesives A and B (thickness: 40 μm).

### DSC (Differential Scanning Calorimetry)

The thermosetting adhesive A or B was subjected to DSC measurement under the following conditions.
Sample amount: 10 mg
Temperature increase rate: 10° C./min
Air or nitrogen atmosphere

For the exothermic peak showing the largest calorific value in the obtained DSC curve, the onset temperature, peak temperature and calorific value were determined. The thermosetting adhesives A and B showed a unified exothermic peak containing two maximum points. The temperature at the intersection point of a tangent to the curve at a position where the gradient of the curve of the exothermic peak is maximum on the lower temperature side than the maximum point on the lower temperature side of the two maximum points of the exothermic peak, and an extension line of the baseline of the DSC curve was taken as the onset temperature. The peak temperature is the temperature at the maximum point having the highest height of the two maximum points.

### Reaction Rate

The thermosetting adhesives A and B were heated at 150° C. or 170° C. for 30 seconds. The thermosetting adhesive after heating was subjected to DSC measurement under the same conditions as above, and the calorific value Q1 of the exothermic peak was determined. The reaction rate was determined from Q1 and the calorific value Q0 of the thermosetting adhesive before heating by the following formula.

$$Reaction rate ( \% ) = \{ ( Q 0 - Q 1 ) / Q 0 \} \times 100$$

### Shear Viscosity

The thermosetting adhesive was laminated using a laminator to form a laminate having a thickness of 500 μm or more. A measurement sample having a size of 10.0 mm×10.0 mm was cut out from the laminate. The shear viscosity (viscosity coefficient) of the measurement sample was measured under the following conditions using a viscoelasticity measuring instrument (product name: ARES-G2, manufactured by TA Instruments). From the viscosity curve showing the relation between shear viscosity and temperature, the shear viscosity at 40° C., 80° C., 130° C., 150° C. or 160° C. and the minimum value of melt viscosity (minimum melt viscosity) were determined. Table 1 also shows the temperature at which the minimum melt viscosity was observed.
Mode: Shear
Temperature increase rate: 10° C./min
Frequency: 10 Hz
Strain: 1%

TABLE 1

| | | Thermosetting adhesive | |
|---|---|---|---|
| Raw materials | | A | B |
| Phenoxy resin | FX-293 | 20 | 20 |
| Epoxy resin | EP-1032H60 | 45 | 45 |
| | YL983U | 15 | 15 |
| | YX7110B80 | 5 | 5 |
| Curing agent | 2MAOK-PW | 2 | 2 |
| Fluxing agent | Glutaric acid | 4 | 4 |
| Organic filler | EXL2655 | 10 | 10 |
| Organic filler | SE2030 | 28 | 18.2 |
| | YA050C-HGF | 42 | 27.3 |
| DSC | Onset | 158 | 160 |
| | temperature [° C.] | | |
| | Peak | 166 | 166 |
| | temperature [° C.] | | |
| | Calorific value | 144 | 174 |
| | [J/g] | | |
| Reaction rate | 150° C./30 s | 12.7 | 5.9 |
| [%] | 170° C./30 s | 28.2 | 28.8 |
| Shear viscosity | 40° C. | 70800 | 87000 |
| [Pa · s] | 80° C. | 5930 | 3250 |
| | 130° C. | 2630 | 1140 |
| | 150° C. | 5330 | 1370 |
| | 160° C. | 40200 | — |
| | Minimum value | 2600 (133° C.) | 1050 (141° C.) |
| | (temperature) | | |

### 3. Manufacturing of Semiconductor Device

### Temporary Pressure Bonding Step

The following first and second semiconductor chips were prepared.

### First Semiconductor Chip:

A semiconductor chip in which connection portions composed of a Cu pillar and a solder bump (melting point: about 217° C.) containing a Sn—Ag alloy, which is provided on the Cu pillar, are provided along the outer circumference portion of the chip body and on the inside of the outer circumference portion at different pitches (size: 7.3 mm square, thickness: 50 μm, total height of Cu pillar and Sn—Ag solder: about 45 μm, number of bumps: 1048 pins, bump pitch along outer circumference portion: 80 μm, bump pitch on inside: 300 μm, product name: WALTS-TEG CC80, manufactured by WALTS CO., LTD.)

### Second Semiconductor Chip

A second semiconductor chip in which connection portions formed by further plating Au (melting point: about 1065° C.) on the Ni plating are provided along the outer circumference portion of the chip body and on the inside of the outer circumference portion at different pitches (chip size: 10 mm square, thickness: 100 μm, product name: WALTS-TEG IP80, manufactured by WALTS CO., LTD.)

A film-shaped thermosetting adhesive A or B cut to a size of 7.3 mm square was attached to the connection surface on which the connection portion of the first semiconductor chip was provided. The first semiconductor chip to which the thermosetting adhesive was attached was picked up by a pressure head of a flip chip bonder (FCB3, manufactured by Panasonic Corporation). The picked up first semiconductor chip was placed on the second semiconductor chip placed on the stage in such a direction in which the thermosetting adhesive is sandwiched between the first semiconductor chip and the second semiconductor chip, and the obtained laminate was then heated and pressurized by the pressure head of the flip chip bonder, thereby obtaining a temporary pressure-bonded body. Temporary pressure-bonded bodies were fabricated under several conditions of temperature, time and pressure shown in Table 2. The temperature is the set temperature of the pressure head, and the pressure is the load applied to the entirety of one first semiconductor chip by the pressure head.

### Main Pressure Bonding Step

Each temporary pressure-bonded body was heated in a heating furnace (Pressurizing Reflow Oven, VPF300HP, manufactured by Shinapex, Co., Ltd.) in a pressurizing atmosphere having a pressure of 0.8 MPa to form a connected body (semiconductor device) for evaluation having a first semiconductor chip and a second semiconductor chip. The temperature of the pressurizing atmosphere was changed under the following temperature condition C1 or C2.
C1: An order of increasing the temperature at 3° C./see and keeping the temperature at 260° C. (main pressure bonding temperature) for 10 minutes (time at a temperature equal to or higher than the melting point of the solder containing Sn—Ag alloy: about 630 seconds)
C2: An order of increasing the temperature at 3° C./see, keeping the temperature at 175° C. (preheating temperature) for 10 minutes, increasing the temperature at 3° C./see, and keeping the temperature at 230° C. (main pressure bonding temperature) for 0.1 seconds (time at a temperature equal to or higher than the melting point of the solder containing Sn—Ag alloy: about 30 seconds)

### 4. Evaluation

### (1) Connectivity

### Electrical Continuity

The electrical continuity between the connection portions of the temporary pressure-bonded body and connected body was measured using a digital multimeter (CDM-09N, manufactured by CUSTOM corporation).
OK: Electrical continuity is detected at the connection portion on the inner circumference side.
NG: Electrical continuity is not detected at the connection portion on the inner circumference side.

### State of Solder

The cross section of the connection portion was observed using an SEM (Scanning Electron Microscope SU1510, manufactured by Hitachi High-Tech Corporation). The state of solder at the cross section of the connection portion was evaluated according to the following criteria.
A: No defects or voids
B: Defects or voids
C: Crushing of solder
D: Poor connection (connection portions not in contact with each other)

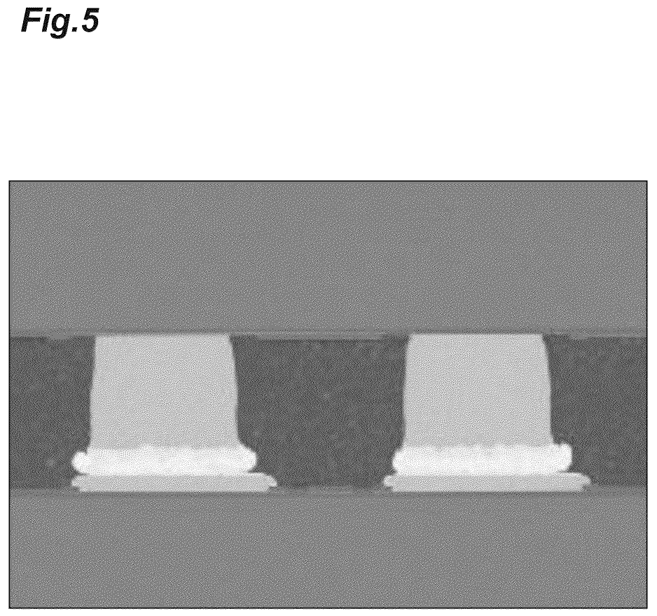

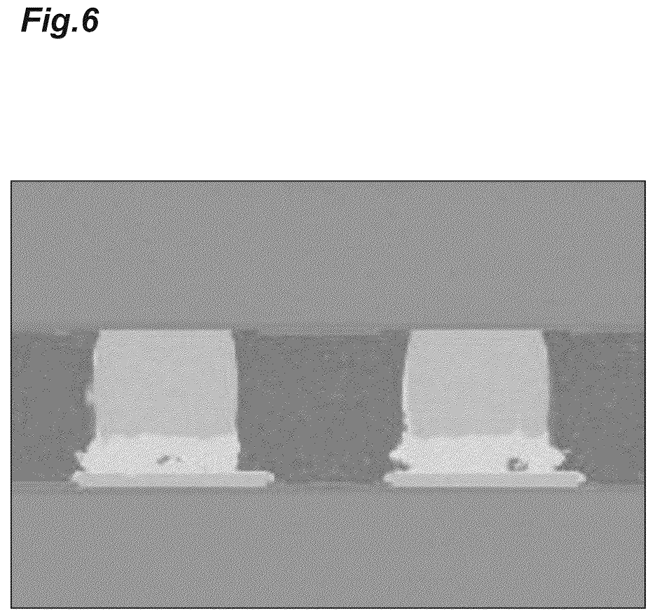

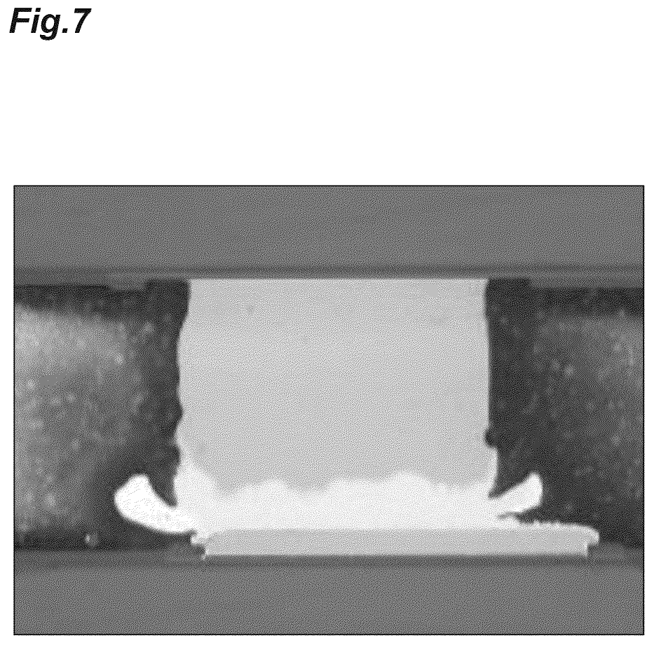

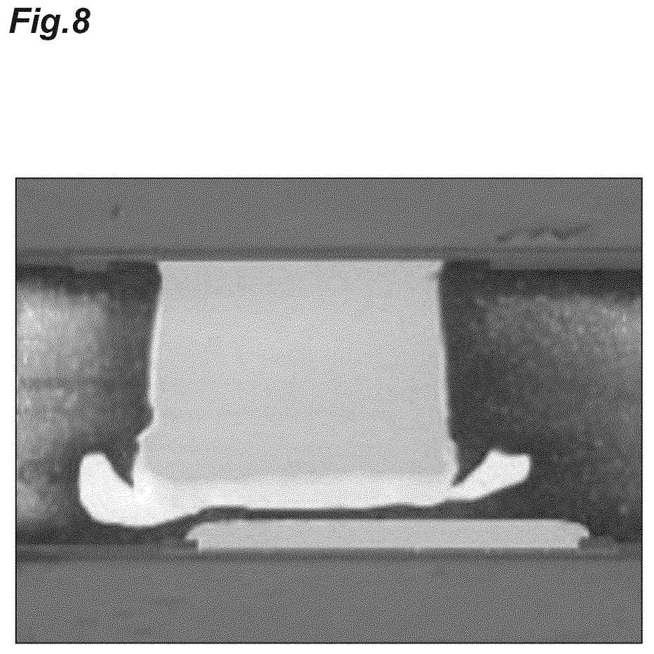

FIG. 5 is a photograph of connection portions in a connected body of Example 4 in which the state of solder is A. FIG. 6 is a photograph of connection portions in a connected body of Example 2 in which the state of solder is B. FIG. 7 is a photograph of a connection portion in a connected body of Comparative Example 2 in which the state of solder is C. FIG. 8 is a photograph of a connection portion in a connected body of Comparative Example 1 in which the state of solder is C and D.

### (2) Void

Regarding the connected body after main pressure bonding, the remaining state of voids on the inside of the connected body was evaluated using SAM (Ultrasonic Digital Imaging Diagnostic Instrument IS-350, manufactured by Insight k.k.). It has been found that voids have been properly removed in all of the connected bodies.

TABLE 2

| | | Example | | | | | Comparative Example | |
|---|---|---|---|---|---|---|---|---|
| | | 1 | 2 | 3 | 4 | 5 | 1 | 2 |
| Thermosetting adhesive | | A | B | B | B | B | A | B |
| Onset temperature | | 158° C. | 160° C. | 160° C. | 160º C. | 160° C. | 158° C. | 160° C. |
| Temporary | Temp. [° C.] | 170 | 170 | 170 | 170 | 180 | 150 | 150 |
| pressure | Time [seconds] | 3 | 3 | 2 | 3 | 3 | 3 | 3 |
| bonding | Load [N] | 70 | 60 | 70 | 70 | 60 | 125 | 125 |
| | Pressure [MPa] | 1.31 | 1.13 | 1.31 | 1.31 | 1.13 | 2.35 | 2.35 |
| Temporary | Electrical | OK | OK | OK | OK | OK | OK | OK |
| pressure- | continuity | | | | | | | |
| bonded | State of | A | A | A | A | A | C | C |
| body | solder | | | | | | | |
| Main | Temp. | C1 | C1 | C1 | C2 | C2 | C1 | C1 |
| pressure | condition | | | | | | | |
| bonding | | | | | | | | |
| Connected | Electrical | OK | OK | OK | OK | OK | NG | OK |
| body | continuity | | | | | | | |
| | State of solder | B | B | B | A | A | C, D | C |

As shown in Table 2, it has been found that deformation of the connection portion (crushing of solder) can be suppressed while favorable electrical continuity is secured by a combination of a temporary pressure bonding step involving heating to a temporary pressure bonding temperature that is equal to or higher than an onset temperature and a main pressure bonding step involving pressurization in a pressurizing atmosphere at a low pressure of 1.50 MPa or less.

### REFERENCE SIGNS LIST

1: first circuit member, 2: second circuit member, 3: thermosetting adhesive layer, 11: metal pillar, 12: bump, 15: first connection portion, 25: second connection portion, 41, 42: pressing member, 50: heating furnace, 100: laminate, 101: temporary pressure-bonded body, 102: connected body (semiconductor device).

1. A method for manufacturing a semiconductor device, the method comprising:
heating and pressurizing a laminate comprising a first circuit member having a first connection portion comprising a first metal material, a second circuit member having a second connection portion comprising a second metal material, and a thermosetting adhesive layer that is interposed between the first circuit member and the second circuit member by a pair of facing pressing members, thereby forming a temporary pressure-bonded body in which the first connection portion and the second connection portion are in contact with each other; and
heating the temporary pressure-bonded body to a predetermined main pressure bonding temperature in a pressurizing atmosphere, thereby forming a connected body in which the first connection portion and the second connection portion are electrically connected by metal joining between the first metal material and the second metal material, wherein
the first circuit member is a semiconductor chip or a semiconductor wafer and the second circuit member is a wiring circuit board, a semiconductor chip, or a semiconductor wafer,
the laminate is pressurized by the pair of pressing members at a predetermined pressure of 1.50 MPa or less,
at least one of the pair of pressing members is heated to a predetermined temporary pressure bonding temperature for a part or whole of time for which the laminate is heated and pressurized by the pair of pressing members, and the temporary pressure bonding temperature is a temperature that is equal to or higher than an onset temperature of the thermosetting adhesive layer and lower than the main pressure bonding temperature,
the onset temperature is an onset temperature of an exothermic peak exhibiting a largest calorific value in a DSC curve obtained by differential scanning calorimetry under a condition in which a sample of the thermosetting adhesive layer is heated at a temperature increase rate of 10° C./min, and
the main pressure bonding temperature is a temperature equal to or higher than at least one of a melting point of the first metal material or a melting point of the second metal material.

2. The method according to claim 1, wherein the predetermined pressure is 0.94 MPa or more and 1.50 MPa or less.

3. The method according to claim 1, wherein the temporary pressure bonding temperature is equal to or higher than the onset temperature and 200° C. or less.

4. The method according to claim 1, wherein the time for which the laminate is heated and pressurized by the pair of pressing members is 5 seconds or less.

5. The method according to claim 1, wherein the thermosetting adhesive layer exhibits a shear viscosity of 10000 Pa·s or less at a temperature lower than the onset temperature by 20° C., and the shear viscosity is a value measured under conditions of a temperature increase rate of 10° C./min, a frequency of 10 Hz, and a strain of 1%.

6. The method according to claim 1, wherein the time for which the temporary pressure-bonded body is heated to a temperature equal to or higher than at least one of a melting point of the first metal material or a melting point of the second metal material in the pressurizing atmosphere is 60 seconds or less.

7. The method according to claim 1, wherein a pressure of the pressurizing atmosphere is higher than atmospheric pressure and 0.90 MPa or less.

8. The method according to claim 1, wherein the thermosetting adhesive layer comprises:
a thermosetting resin having a molecular weight of less than 10000;
a curing agent for the thermosetting resin; and
a polymer component having a weight average molecular weight of 10000 or more.

9. The method according to claim 8, wherein the polymer component has a glass transition temperature of 200° C. or less.

10. The method according to claim 1, wherein the thermosetting adhesive layer exhibits a shear viscosity of 10000 Pa·s or more at 40° C.
